(19) United States
(12) Patent Application Publication
(10) Pub. No.: US 2024/0326625 A1
(43) Pub. Date: Oct. 3, 2024

(54) Forced Symmetry Insulation Monitoring Device and Method

(71) Applicant: ABB E-mobility B.V., Delft (NL)

(72) Inventor: Stefan J. Raaijmakers, Delft (NL)

(73) Assignee: ABB E-mobility B.V., Delft (NL)

(21) Appl. No.: 18/293,446

(22) PCT Filed: Mar. 4, 2022
(86) PCT No.: PCT/IB2022/051949

§ 371 Date: Jan. 30, 2024

Related U.S. Application Data
(60) Provisional application No. 63/227,697, filed on Jul. 30, 2021.

(51) Int. Cl. B60L 53/60; G01R 19/00; G01R 27/18; G01R 31/52

(52) U.S. Cl. CPC B60L 53/60; G01R 19/0084; G01R 27/18; G01R 31/52

(57) ABSTRACT

The present disclosure provides a forced symmetry IMD and a method to control the forced symmetry IMD. The system comprises an electric system power source configured to deliver electrical power to a bus, the bus including a first bus bar and a second bus bar; a common node connected across the first bus bar and the second bus bar, the common node having a common voltage; and a forced symmetry insulation monitoring device (IMD) disposed along an IMD node connected to at least one of the first bus bar and the second bus bar, the forced symmetry IMD comprising a connection to ground and one or more IMD power sources, wherein the one or more IMD power sources of the forced symmetry IMD is configured to control the common voltage on the common node based on a currently detected common voltage and a reference voltage signal.

### CROSS-REFERENCE TO RELATED APPLICATIONS

This patent application claims the benefit of U.S. Provisional Patent Application No. 63/227,697, filed Jul. 30, 2021, which is incorporated by reference herein in its entirety.

### BACKGROUND OF THE DISCLOSURE

In electric vehicle charging systems, electrical power is provided in an electrical distribution grid onto which electric vehicle chargers are connected. Electric vehicles can thus connect to the electric vehicle chargers and draw power therefrom to recharge batteries mounted onto the electric vehicles. As can be appreciated, the power grids providing power to the electric vehicle chargers (EVSE) and also the electric vehicles themselves (EV) are installed and operate in areas accessible by the vehicles, and are thus exposed to environmental factors such as weather, interaction with people and animals, and the like. Because the electrical power transferred through these grids is often quite appreciable, for example, 1000 volts (V) direct current (DC), safety devices are required to avoid injury to persons and animals that may come into contact with electric conductors or other components. The need for safety devices is also enhanced when considering system and component degradation over time.

One type of safety device used in the past is an insulation monitor device (IMD), which electrically determines leakage current and leakage capacitance of electric power from the power grid or its components to the environment. For example, a person or animal coming into contact with a live electrical conductor may cause a leakage current from the system to flow through that person or animal. In such instances, the IMD may detect the leakage current and in response, seek to protect to the person from injury.

Charging systems may require an IMD or leakage current detection, to detect the first fault to earth and switch off the system. IMD's are described in International Electrotechnical Commission (IEC) 61577-8. In one known arrangement, an earth leakage detection method is used that combines a power source connected between two gap resistors between the two bars of a DC bus. This is shown in FIG. 1A. In FIG. 1A, a charging system 100 includes an alternating current/direct current (AC/DC) converter 102 that provides DC electrical power to a first DC Bus bar 104, for example, disposed at a positive voltage (DC+) and a second DC Bus Bar 106, disposed at a negative voltage (DC−). The converter 102 is part of an EV charging system, EVSE 103, and includes a traditional IMD 101. One or more vehicles (e.g., EVs) may be connected to the EVSE 103 for charging. In the event a person 110, representing a ground path 112 and having a resistance Rh is connected to a conductor, the traditional IMD 101 is configured to set the power of the system 100 to shut-down charging of the EV based on the prospective touch current exceeding a threshold that may harm a person, which may protect the person before they touch one of the DC rails. The traditional IMD 101 in the example shown in FIG. 1A includes two gap resistors Rimd+ and Rimd−, each having a respective power source Vimd+ and Vimd−, to detect a drop in voltage on either DC Bus bar 104 and/or 106.

A voltage/current detector disposed between the two gap resistors may indicate grounding of one of the two DC bus bars and shut off power to the DC bus. In other implementations, the IMD on the electric vehicle itself may be used in the same fashion while the EV is connected to the EVSE that is powered by the DC bus.

FIGS. 1B and 1C show further examples of traditional IMDs 101. In particular, FIG. 1B shows a traditional IMD 101 with a detector/resistor R9, a voltage V4, and two resistors R7 and R8. FIG. 1C is similar to FIG. 1B, but further includes two switches S2 and S3.

One main function of the traditional IMD 101 is to detect a low resistance or short to earth and stop the charging process. On a first fault to earth, only a small current may flow between the DC circuit and an unexpected conductor to ground, for example, a person or animal (e.g., protective earth (PE) conductor). Switching off power to the DC bus by the traditional IMD 101 may protect the PE conductor because a large current may flow through the PE conductor in the case of a second fault to earth.

In IEC 61851-23:2014, the trip level of the traditional IMD 101 is set typically to 1000/V times the maximum output voltage of the EVSE. In such a condition, the traditional IMD 101 can be used to protect against a harmful electric shock in case of a person or animal accidentally coming into contact with and/or electrically touching, e.g., through a wet surface, a bare DC bus bar or conductor. While such contact may be painful to the person or animal, per IEC 61577-8, this commonly used trip level does not include or consider the impedance of the traditional IMD 101 itself, so this type of protection is not well enough defined to serve its purpose.

Safety standard IEC 61851-23, edition (ed.) 2.0, introduces more clear definitions to limit the touch current and energy/touch impulse current to be below the threshold of strong involuntary muscular contractions (Curve b in IEC 60479-1:2018 due to leakage currents), and below the threshold of ventricular fibrillation (c1-curve in IEC 60479-1:2018 or IEC 60479-2:2019 due to the touch impulse current). The trip-level of the traditional IMD 101 may have a fixed value of 100f/V times the maximum output voltage of the system. These curves taken from the standard are shown in FIG. 2A, which illustrates a log-log graph of milliamps (mA) of current plotted along the horizontal axis, and time of exposure plotted along the vertical axis. As can be seen in this graph, “a” represents a limit line of electrical power passing through the person or animal that is imperceptible, “b” represents power that is perceptible but causes no muscle contraction, above “b” represents power that causes muscle contraction but has reversible effects and can be painful, “c1” represents the limit for which the person has no chance of heart fibrillation, “c2” represents the limit for which the person has up to 5% probability of heart fibrillation, and “c3” represents the limit above which the person has a more than 50% chance of heart fibrillation.

As can be seen in FIG. 2A, for a typical system operating at 920V, the leakage current limit “A” is below the “b” line, and the impulse current limit “B” is right on the C1 line, which creates a safe condition. However, there is the desire for faster charging of vehicles, which can be accomplished by increasing the voltage difference across the DC bus bars. However, as can be deduced by considering FIG. 2A, any increase in the voltage of the DC bus bar may cause the points A and B to also move to the right and exceed the safe limits of an unintentional touching, as shown in FIG. 2B. In the condition shown in FIG. 2B, the voltage on the DC bus is increased to 1250V DC, and the total Y-capacitance is increased to 16 uF.

### BRIEF SUMMARY

A first aspect of the present disclosure provides a forced symmetry IMD and a method to control the forced symmetry IMD. The system comprises an electric system power source configured to deliver electrical power to a bus, the bus including a first bus bar and a second bus bar; a common node connected across the first bus bar and the second bus bar, the common node having a common voltage when electric power is delivered to the bus; and a forced symmetry insulation monitoring device (IMD) disposed along an IMD node connected to at least one of the first bus bar and the second bus bar, the forced symmetry IMD comprising a connection to ground and one or more IMD power sources, wherein the one or more IMD power sources of the forced symmetry IMD is configured to control the common voltage on the common node based on a currently detected common voltage and a reference voltage signal.

According to an implementation of the first aspect, the system further comprises: a first detector configured to detect the currently detected common voltage at the common node and provide the currently detected common voltage to a controller; and the controller is configured to: receive the currently detected common voltage; and direct the one or more IMD power sources to provide current to the forced symmetry IMD to match the reference voltage signal using a feedback loop and the currently detected common voltage.

According to an implementation of the first aspect, the system further comprises: a second detector configured to detect a node voltage at the IMD node and provide the node voltage to the controller, and wherein the controller is configured to direct the one or more IMD power sources to provide current to the forced symmetry IMD to match the reference voltage signal using the feedback loop, the currently detected common voltage, and the node voltage.

According to an implementation of the first aspect, the controller is configured to: determine a reference voltage signal for the forced symmetry IMD; and change a characteristic of the reference voltage signal, wherein the characteristic of the reference voltage signal is a type of wave, a frequency of the reference voltage signal, an amplitude of the reference voltage signal, or slope of edges of the reference voltage signal.

According to an implementation of the first aspect, the type of wave is one or more square waves, one or more sinusoidal waves, or a mixture of both the one or more square waves and the one or more sinusoidal waves.

According to an implementation of the first aspect, the controller configured to change the characteristic of the reference voltage signal based on operational status of the bus, wherein the operational status of the bus comprises balanced resistance to ground, unbalanced resistance to ground, capacitance to ground, voltage between the first bus bar and the second bus bar, or noise within the system.

According to an implementation of the first aspect, the controller is configured to: determine a resistance to ground value based on the common voltage at the common node and a current at the IMD node; control the electric power source based on the resistance to ground value.

According to an implementation of the first aspect, the controller is configured to: determine a capacitance to ground value based on the common voltage at the common node and a current at the IMD node, and wherein controlling the electric system power source is further based on the capacitance to ground value, first voltage of the first bus bar to ground value, second voltage of the second bus bar to ground value, third voltage between first bus bar and second bus bar value, and a predetermined human body resistance value.

According to an implementation of the first aspect, the controller is configured to control the electric power source by providing a notification to a separate device indicating a warning or to service the system, or de-energize the electric system power source.

According to an implementation of the first aspect, the forced symmetry IMD further comprises a first voltage source and a second voltage source, wherein the first voltage source is located between a first IMD power source, of the one or more IMD power sources, and the IMD node, and wherein the second voltage source is located between a second IMD power source, of the one or more IMD power sources, and the IMD node.

According to an implementation of the first aspect, the forced symmetry IMD further comprises a first diode and a second diode, wherein the first diode is located between the first IMD power source and the first bus bar, and wherein the second diode is located between the second IMD power source and the second bus bar.

According to an implementation of the first aspect, the forced symmetry IMD further comprises a first transistor and a second transistor, wherein a drain of the first transistor is connected to a first bus bar, a source of the first transistor is connected to the IMD node, and a gate of the first transistor is connected to the one or more IMD power sources, and wherein a drain of the second transistor is connected to a second bus bar, a source of the second transistor is connected to the IMD node, and a gate of the second transistor is connected to the one or more IMD power sources.

According to an implementation of the first aspect, the forced symmetry IMD further comprises a first transistor, wherein a drain of the first transistor is connected to the first bus bar, a gate of the first transistor is connected to a first resistor and a second resistor, and a source of the first transistor is connected to a positive voltage source, and wherein the first resistor is connected to a first IMD power source of the one or more IMD power sources.

According to an implementation of the first aspect, the electric system power source is configured to deliver electrical power to the bus to charge or discharge a storage device.

According to an implementation of the first aspect, the storage device is a battery of an electric vehicle.

In a second aspect, a forced symmetry insulation monitoring device (IMD) is provided. The forced symmetry IMD comprises a connection to ground; and one or more IMD power sources, wherein the forced symmetry IMD is disposed along an IMD node connected to at least one of a first bus bar and a second bus bar of a bus, wherein the one or more IMD power sources of the forced symmetry IMD is configured to control the common voltage on the common node based on a currently detected common voltage and a reference voltage signal.

According to an implementation of the second aspect, the forced symmetry IMD further comprises a first voltage source and a second voltage source, wherein the first voltage source is located between a first IMD power source, of the one or more IMD power sources, and the IMD node, and wherein the second voltage source is located between a second IMD power source, of the one or more IMD power sources, and the IMD node.

According to an implementation of the second aspect, the forced symmetry IMD further comprises a first diode and a second diode, wherein the first diode is located between the first IMD power source and the first bus bar, and wherein the second diode is located between the second IMD power source and the second bus bar.

According to an implementation of the second aspect, the forced symmetry IMD further comprises a first transistor and a second transistor, wherein a drain of the first transistor is connected to a first bus bar, a source of the first transistor is connected to the IMD node, and a gate of the first transistor is connected to the one or more IMD power sources, and wherein a drain of the second transistor is connected to a second bus bar, a source of the second transistor is connected to the IMD node, and a gate of the second transistor is connected to the one or more IMD power sources.

According to an implementation of the second aspect, the forced symmetry IMD further comprises a first transistor, wherein a drain of the first transistor is connected to the first bus bar, a gate of the first transistor is connected to a first resistor and a second resistor, and a source of the first transistor is connected to a positive voltage source, and wherein the first resistor is connected to a first IMD power source of the one or more IMD power sources.

### BRIEF DESCRIPTION OF THE SEVERAL VIEWS OF THE DRAWING(S)

FIGS. 1A-C are schematic views of a charging system as well as examples of traditional IMDs in accordance with the disclosure.

FIGS. 2A and 2B are graphical representations in accordance with the disclosure.

FIG. 3 is a graphical representation in accordance with the disclosure.

FIG. 4 is graphical representation of the C-1 limit vs. the resistance of a human body in accordance with the disclosure.

FIG. 5 is a schematic view of a charging system with a forced symmetry IMD in accordance with the disclosure.

FIG. 6 is a circuit schematic for an IMD in accordance with the disclosure.

FIG. 7A-7C are traces of fault modes in a circuit in accordance with the disclosure.

FIG. 8 is another circuit schematic for an IMD in accordance with the disclosure.

FIGS. 9-11 are traces of different operating conditions of the IMD shown in FIG. 8.

FIG. 12 is another circuit schematic for an IMD in accordance with the disclosure.

FIG. 13 is another circuit schematic for an IMD in accordance with the disclosure.

FIG. 14 is another circuit schematic for an IMD in accordance with the disclosure.

FIG. 15 is a schematic illustration of a block diagram depicting an exemplary control system for controlling the forced symmetry IMD in accordance with the disclosure.

FIG. 16 is another circuit schematic for an IMD in accordance with the disclosure.

FIG. 17 is another circuit schematic for an IMD in accordance with the disclosure.

### DETAILED DESCRIPTION OF PREFERRED EMBODIMENTS

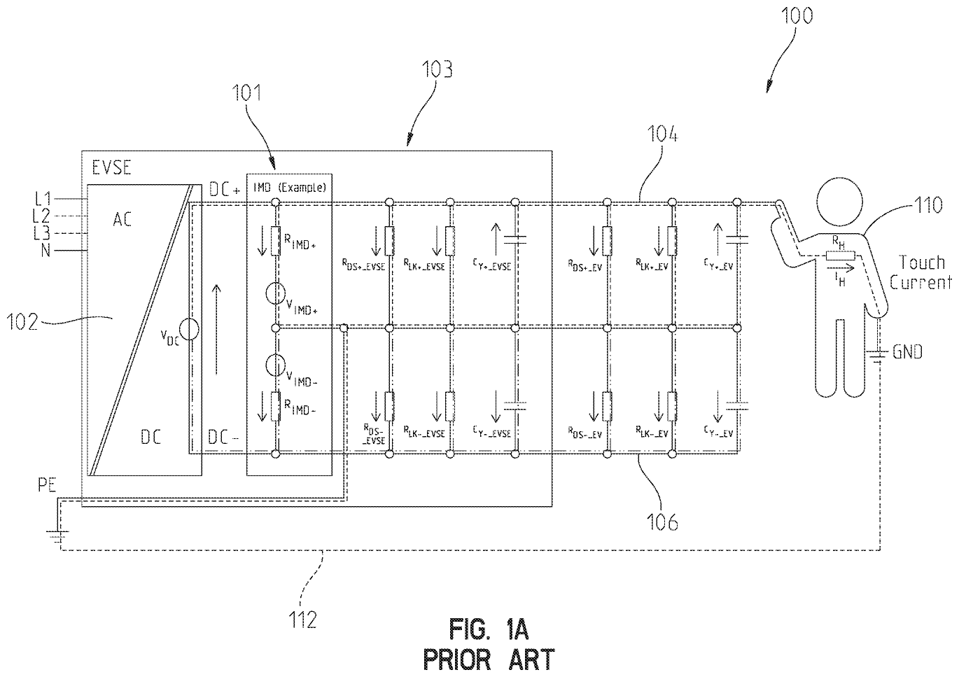

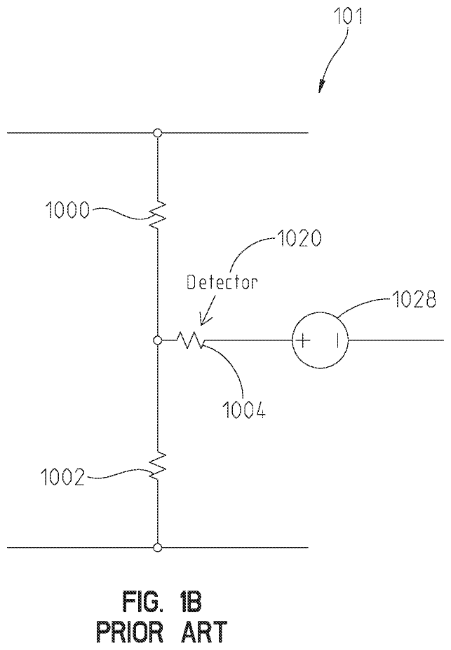

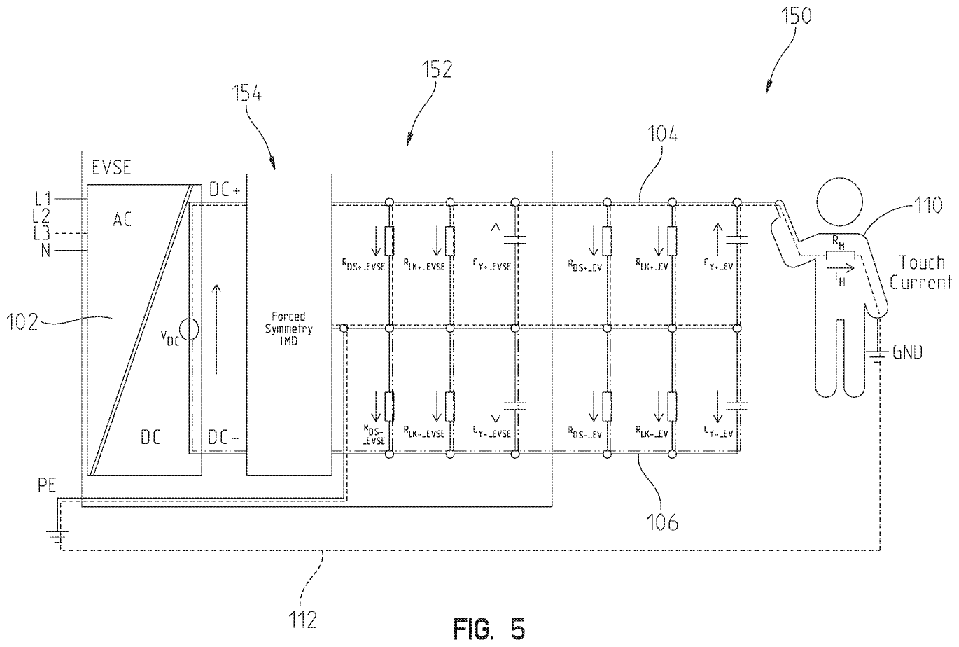

In reference to the system 100 of FIG. 1A with the traditional IMD 101, the present disclosure provides different embodiments that improve upon the traditional IMD 101. In particular, FIG. 5 shows a system 150 that includes similar components to the system 100 of FIG. 1A. For instance, FIG. 5 shows a person 110 as well as an AC/DC converter 102 that provides DC electrical power to a first DC Bus bar 104, for example, disposed at a positive voltage (DC+) and a second DC Bus Bar 106, disposed at a negative voltage (DC−).

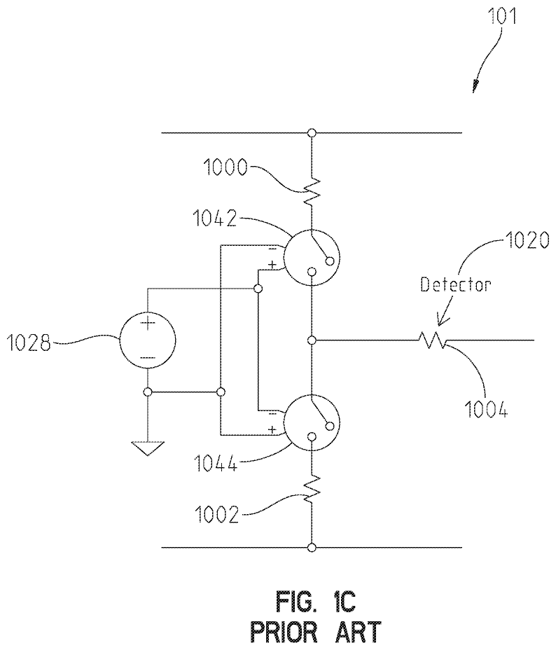

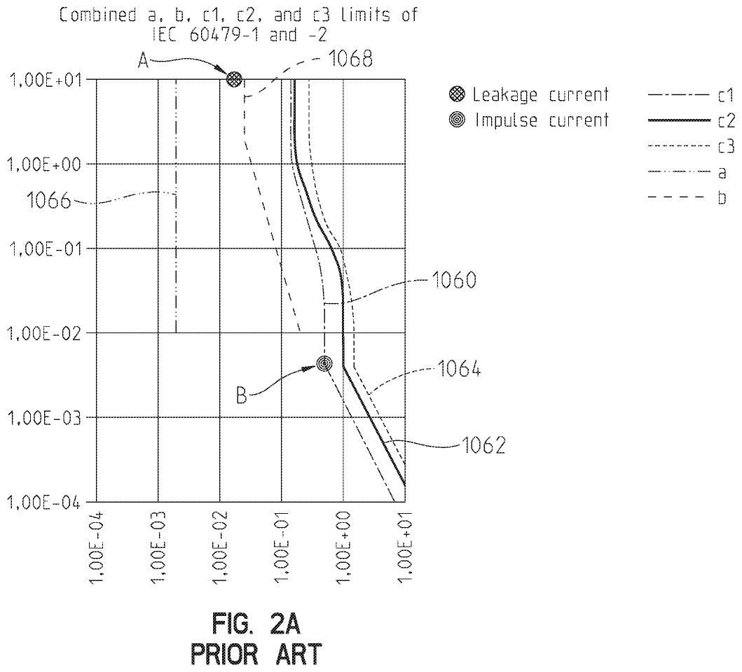

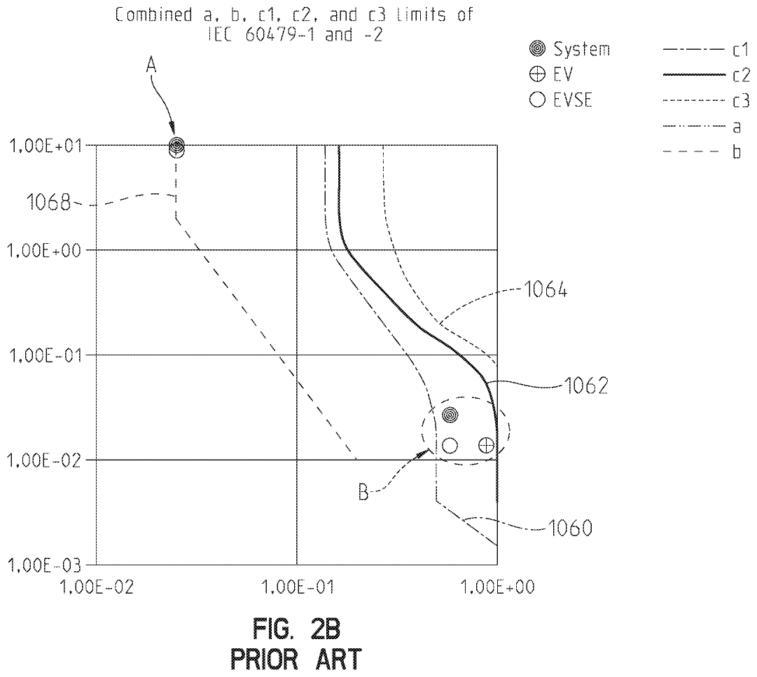

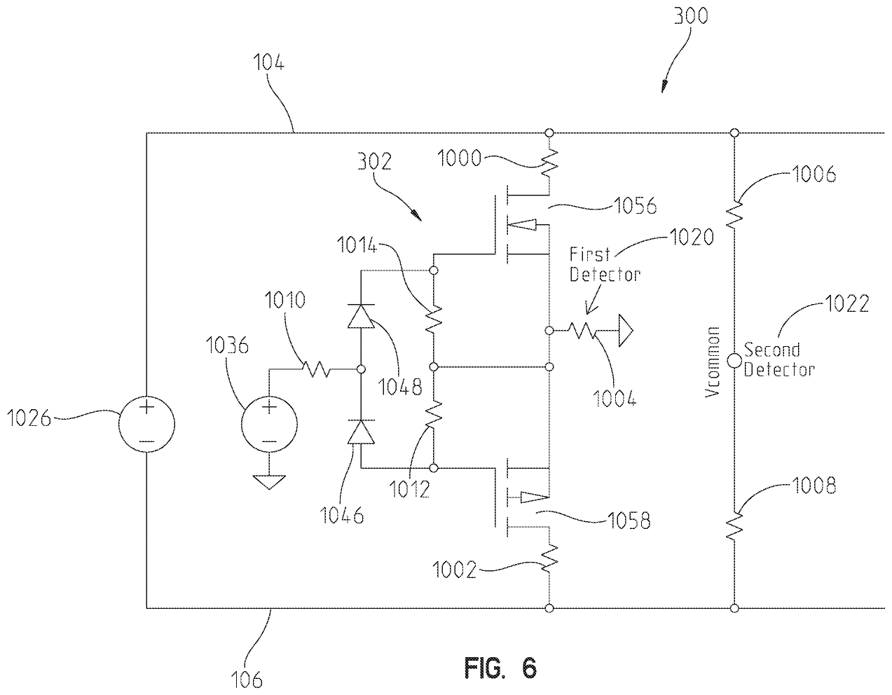

However, the system 150 includes an EVSE 152 with a forced symmetry IMD 154. The forced symmetry IMD 154 is configured to provide an improvement over the existing state of the art and solve the particular problems and disadvantages of increased electrical power transfer to a person during a fault to be below a safe limit while also permitting operation of the DC Bus bars at a higher voltage, e.g., 1250V DC. For example, the forced symmetry IMD 154 may be configured to use a detected common mode voltage (Vcommon) and/or a reference voltage to provide an acceptable prospective leakage current and impulse current passing through a person can be minimized and maintained within safe limits, i.e., below the level C-1 as shown in FIGS. 2A and 2B. In particular, a controller may inject current into the forced symmetry IMD 154 such that the Vcommon follows the reference voltage. In other words, the forced symmetry IMD 154 is advantageously able to float or balance a voltage difference between the two DC bus bars such that an acceptable leakage current and impulse current passing through a person can be minimized and maintained within safe limits. FIGS. 6, 8, 12, 13, and 14 show different embodiments of the forced symmetry IMD 154 and will be described in further detail below.

In EV charging, there is always a need for more current and more voltage. Whenever this is increased, it should still meet the same requirements for safety, and/or additional measures may be needed. For the future Megawatt Charging System (MCS), the prospective maximum working voltage is 1250V, and current is 3000 A. Due to the higher power levels, more y-capacitance is needed to meet electromagnetic compatibility (EMC) requirements, this may be in the range of 10-25 microfarads (uF) in total for the system, instead of 5 uF for certain systems in the current standards.

The higher voltage and Y-capacitance may pose a problem for meeting the requirements for touch current and energy/impulse touch current. Also, the trip-level and measurement resistances may be higher to meet the leakage current requirements at higher voltage.

To stay in line with International Organization for Standardization (ISO) 6469-3, and United Nations Economic Commission for Europe (UN ECE) R100, the trip level for the IMDs of the new system must remain 1000V, therefore should be set to 125kΩ for a 1250V system.

From Annex H, of the IEC 61851-23:FDIS Draft:Compliance to the Y-capacitance limit of the DC EV supply equipment is tested in 8.105.1. Compliance to the limitation of steady state touch current and touch impulse current is tested in 8.101.4. Guidance on the measurement of the mandatory total y-capacitance limit in the EV is given in Annex A of ISO 17409:2020.

Table 1, reproduced below, illustrates calculations that allow for an evaluation of tradeoffs that can be used for design verification of the DC EV supply equipment.

TABLE 1

| Quantity | | | | |
|---|---|---|---|---|
| Symbol | Quantity Name | Calculation Formula | Value | Unit |
| V_{DC} | Maximum output | | 920 | Volt |
| | voltage | | | (V) |
| V_{IMD+} | IMD measurement | | 50 | V |
| | voltage+ | | | |
| V_{IMD-} | IMD measurement | =−V_{IMD+} | −50 | V |
| | voltage− | | | |
| R_{IMD+} | IMD measurement | | 120,000E+03 | Ohm |
| | resistance+ | | | (Ω) |
| R_{IMD-} | IMD measurement− | | 120,000E+03 | Ω |
| R_{DS+}_{_{—}}_{EVSE} | Designed resistance | | 2,000E+06 | Ω |
| | EVSE+ | | | |
| R_{DS-}_{_{—}}_{EVSE} | Designed resistance | | 2,000E+06 | Ω |
| | EVSE− | | | |
| R_{LK+}_{_{—}}_{EVSE} | Leakage resistance | | 100,000E+06 | Ω |
| | EVSE+ | | | |
| R_{LK-}_{_{—}}_{EVSE} | Leakage resistance | | 100,000E+06 | Ω |
| | EVSE− | | | |
| R_{DS+}_{_{—}}_{EV} | Designed resistance | | 100,000E+06 | Ω |
| | EV+ | | | |
| R_{DS-}_{_{—}}_{EV} | Designed resistance | | 100,000E+06 | Ω |
| | EV− | | | |
| R_{LK+}_{_{—}}_{EV} | Leakage resistance | | 100,000E+06 | Ω |
| | EV+ | | | |
| R_{LK-}_{_{—}}_{EV} | Leakage resistance | | 112,000E+03 | Ω |
| | EV− | | | |
| R_{H} | Human body | | 575 | Ω |
| | representation | | | |
| C_{Y+EV} | Y capacitance EV+ | | 869.57E−09 | Farad |
| | | | | (F) |
| C_{Y-EV} | Y capacitance EV− | | 869.57E−09 | F |
| C_{Y+EVSE} | Y capacitance | | 500.00E−09 | F |
| | EVSE+ | | | |
| C_{Y-EVSE} | Y capacitance | | 500.00E−09 | F |
| | EVSE− | | | |
| C_{TOT} | Total Y capacitance | =C_{Y+EV} + C_{Y-EV} + C_{Y+EVSE} + C_{Y-EVSE} | 2.74E−06 | F |
| | system | | | |
| R_{SYS+} | System resistance+ | =1/((1/R_{DS+}_{_{—}}_{EVSE}) + (1/R_{LK+}_{_{—}}_{EVSE}) + | 575 | Ω |
| | | (1/R_{DS+}_{_{—}}_{EV}) + (1/R_{LK+}_{_{—}}_{EV}) + (1/R_{H})) | | |
| R_{SYS-} | System Resistance− | =1/((1/R_{DC-}_{_{—}}_{EVSE}) + (1/R_{LK-}_{_{—}}_{EVSE}) + | 105,836E+03 | Ω |
| | | (1/R_{DS-}_{_{—}}_{EV}) + (1/R_{LK-}_{_{—}}_{EV})) | | |
| R_{SYS+NH} | R_{SYS+} without | =1/((1/R_{DS+}_{_{—}}_{EVSE}) + (1/R_{LK+}_{_{—}}_{EVSE}) + | 1,887E+06 | Ω |
| | human | (1/R_{DS+}_{_{—}}_{EV}) + (1/R_{LK+}_{_{—}}_{EV})) | | |
| R_{SYS} | Total system | =1/((1/R_{SYS+}) + (1/R_{SYS-})) | 572 | Ω |
| | resistance | | | |
| R_{IMD} | Total IMD | =1/((1/R_{IMD+}) + (1/R_{IMD-})) | 60,000E+03 | Ω |
| | resistance | | | |
| R_{SYS}_{_{—}}_{NH} | Rsys without human | =1/((1/R_{SYS+}_{_{—}}_{NH}) + (1/R_{SYS-})) | 100.215 | Ω |
| R_{SYS}_{_{—}}_{NH+IMD} | Rsys including IMD | =1/((1/R_{SYS}_{_{—}}_{NH}) + (1/R_{IMD+}) + (1/R_{IM}_{D-})) | 37.530 | Ω |
| | resistance | | | |
| V₁ | Thevenin equiv. V₁ | =V_{DC}*(R_{SYS-}/(R_{SYS+} + R_{SYS-})) | 915 | V |
| V₂ | Thevenin equiv. V₂ | =V_{IMD-} + (V_{DC} − V_{IMD+} − V_{IMD-})* | 410 | V |
| | | (R_{IMD-}/(R_{IMD+} + R_{IMD-})) | | |
| V₁_{_{—}}_{NH} | V1 without human | =V_{DC}*(R_{SYS-}/(R_{SYS+NH} + R_{SYS-})) | 48.86 | V |
| V_{PE} | V_{PE} vs V_{DC-} | =V₂ + (V₁ − V₂)*(R_{IMD}/(R_{SYS} + R_{IMD})) | 910.26 | V |
| V_{PE}_{_{—}}_{NH} | V_{PE} without human | =V₂ + (V₁_{_{—}}_{NH} − | 274.76 | V |
| | | V₂)*(R_{IMD}/(R_{SYS}_{_{—}}_{NH} + R_{IMD})) | | |
| I_{H} | Steadystate body | =(V_{DC} − V_{PE})/R_{H} | 16,933E−03 | Amps |
| | current | | | (A) |
| I_{PK} | Peak body current | =(V_{DC} − V_{PE}_{_{—}}_{NH})/R_{H} | 1,122E+00 | A |
| I_{PK}_{_{—}}_{RMS} | RMS body current | =I_{PK}/√6 | 0.458121474 | A |
| T_{3RC} | Duration of impulse | =3*(1/((1/R_{SYS}) + (1/R_{IMD})))*C_{TOT} | 4.65E−03 | Seconds |
| | | | | (s) |
| E | Energy through | =((V_{DC} − V_{PE}_{_{—}}_{NH})² − (V_{DC} − | 570.08E−03 | Joules |
| | body | V_{PE})²)*½*C_{TOT} | | (J) |
| T_{IMD} | Minimum IMD | =15*R_{IMD}*C_{TOT} | 2.465217391 | s |
| | reaction time | | | |

The calculations in Table 1 represent a nominal condition in which a DC Bus operating at 920V meets safety requirements. Reference is made to FIG. 2A, previously described, in which the points A and B are within safe limits.

When the voltage of the system is increased to 1250V, certain parameters are updated as shown in Table 2 below:

TABLE 2

| | | |
|---|---|---|
| Rimd+ | IMD measurement resistance | 90,000E+03 |
| Rimd− | IMD measurement resistance | 250,000E+03 |
| Rds+_EVSE | Designed resistance EVSE+ | 2,000E+06 |

In this condition, as shown in FIG. 2B, the IMD resistance to 2×90 k and the capacitance to 16 uF total, can still meet the leakage current requirement, but not the energy/impulse current requirement (shown in “B”).

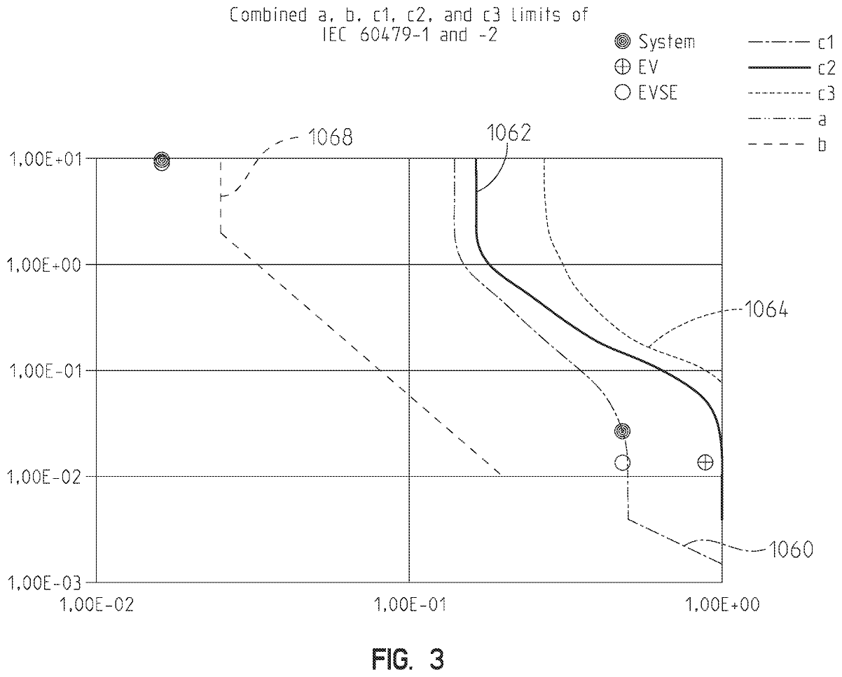

FIG. 3 shows the effect of the increase in resistance of the resistors from Table 2 above. As shown, the asymmetry is compensated by the forced symmetry IMD 154 with the resistance values shown above in Table 2. As such, as compared to FIG. 2B, several of the points from “B” in FIG. 2B are further left on the graphical representation of FIG. 3 and in fact are intersecting with c1. Therefore, the forced symmetry IMD 154 moves these points to the left and are thus making the overall system safer.

The IMDs in accordance with the present disclosure (e.g., the forced symmetry IMDs 154) solve the problems of the existing systems and maintain safe limits for both leakage current (“A”) and energy/impulse current (“B”) as shown in FIGS. 2A and 2B by modifying the IMD measurement resistance to keep the system balanced, to selectively control leakage current and energy/impulse current and bring them to a level that is below what is acceptable and safe.

After altering an IMD circuit to keep the system symmetric, even in the presence of asymmetric leakage, i.e. current leakage that is different from one DC Bus bar to another, the system (e.g., the system 150) can operate at up to 1250V, or higher, and still meet the appropriate limits for touch current and energy/touch impulse current.

However, an increase in the resistance of the IMD may also increase measurement times, by up to two times, because the measurement impedance to ground of the IMD is higher. Practically speaking, in the forced symmetry IMDs 154 in accordance with the disclosure, the ‘common mode’ voltage to ground is controlled to stay below the c1 threshold and may be modulated with a specific signal to measure the resistance and capacitance of the system. Various thresholds can be used on those measured values if the system exceeds a specific limitation.

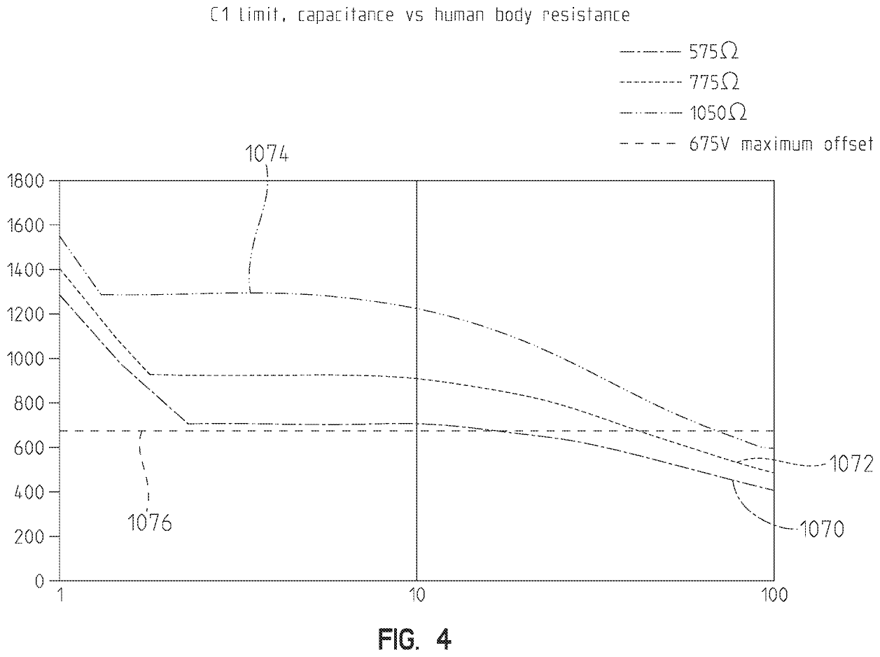

To protect against the c1 limit, the voltage of each conductor to ground needs to be limited. This voltage limit depends on the capacitance of the complete system, and the representative resistance of the human body. In reference to the circuit shown in FIG. 1A for the system 100, and the c1 limits of IEC 60479-1 and -2, one can derive the figure shown in FIG. 4, in which the c-1 limits are plotted for various assumed resistance levels of a human body with respect to voltage.

The forced symmetry IMDs 154 in accordance with the disclosure are advantageously arranged to control the system's resistance to ground by incorporating a variable impedance device, for example, a transistor operating in its linear range, or another variable impedance device, such that measurement of resistance and capacitance to ground, for each DC Bus bar separately, is possible and controllable, connected in line with a power source, which together operate to match a common voltage existing between the two bus bars across gap resistors. In some instances, a controller or processor may be used to in conjunction with the forced symmetry IMD 154 to control the system's (e.g., system 150) resistance to ground and/or limit the voltage and/or capacitance to ground.

In such a condition, if a maximum working voltage of 1250V is used, and a power of +/−50V is used for measuring the impedance, the voltage to ground per rail or bus bar can be limited to 675V, which is below the safe threshold for any human body, as shown in FIG. 4. This allows up to +/−16 uF given a human body resistance of 575Ω, or any other value that is desired and assumed to be representative of most human bodies that may come into contact with a bare conductor.

Having a minimum impedance to ground for the measurement circuit in order to protect against the worst-case leakage current of a person touching one of the live conductors is preferred. This, in combination with the trigger level and at the maximum voltage, allows for the voltage to remain under the threshold under normal operation. Based on the leakage resistance being lower, the maximum voltage may be exceeded, causing the forced symmetry IMD 154 to trip either due to the violation of the minimum resistance of the system, or due to the violation of the voltage to ground. In addition to the resistance to ground, the forced symmetry IMD 154 can measure and/or be used to measure the capacitance and adapt the voltage threshold accordingly. In one embodiment, the forced symmetry IMD 154 can have a fixed voltage threshold and optionally trigger on a capacitance that is too high.

All or some of these parameters can be configuration options: Equivalent human body resistance, C1/C2/C3/other limits based on the effects on the human body (according it IEC 60479 series, maximum voltage to ground per rail, maximum capacitance to ground, minimum resistance to ground, minimum symmetrical resistance to ground, minimum asymmetrical resistance to ground, etc. These triggers can have different filtering options to facilitate different reaction times.

The forced symmetry of the resistance of each of both rails to ground has additional benefits, for instance in the case of pre-charge. If the EV and EVSE have some asymmetry compared to ground, there could be an inrush current even when closing one contactor. If both EV and EVSE are kept symmetrical before closing the contactors, this effect may be minimized. This may require coordination between EV and EVSE, to ensure minimal voltage difference, or one side follows the other, or the forced symmetry IMD 154 function is temporarily disabled and both systems are kept perfectly symmetrical by the balancing circuit.

The symmetry may be disturbed by short-time events, for instance switching contactors, ramping up/down the output voltage of the charger, insertion of the connector, measurement circuits over contactors, etc. The forced symmetry IMD 154 may have to filter out this type of noise, and if it cannot some triggers may need to be slowed down, or the forced symmetry IMD 154 may have to treat this as a fault and stop the charging process.

In all the traces shown in the figures that follow, three conditions are shown in sequence—a no fault condition, an asymmetric fault condition, and a symmetric fault condition.

In a traditional IMD (e.g., traditional IMD 101), an asymmetrical fault at or just above the threshold can cause large offsets of the voltage readings at each of the two DC Bus bars. The traditional IMD 101 may use detector disposed between two gap resistors extending across the two DC Bus bars in parallel with the power supply to the DC Bus. This is shown in FIG. 1B. Alternatively, the traditional IMD 101 may use a switched resistor, operating in an on/off condition, which can cause large voltage swings even if there is no fault. This is shown in FIG. 1C.

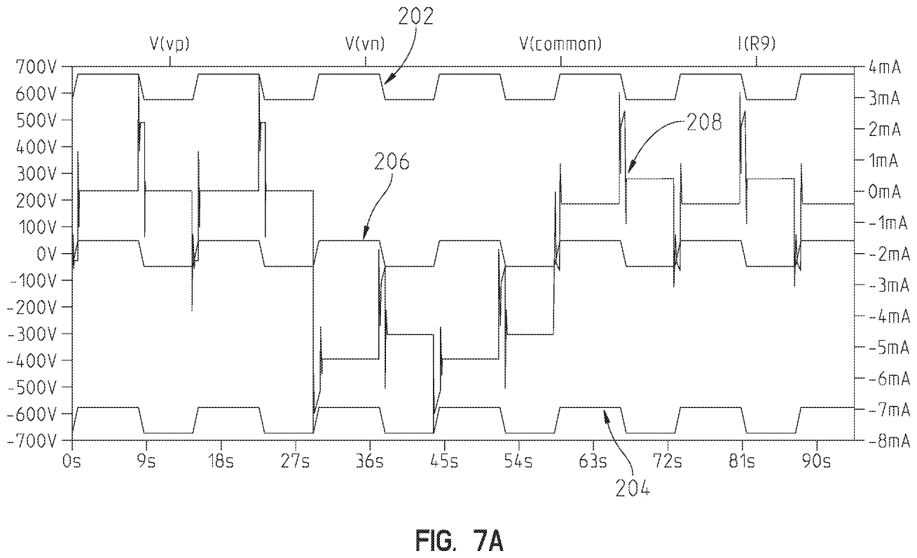

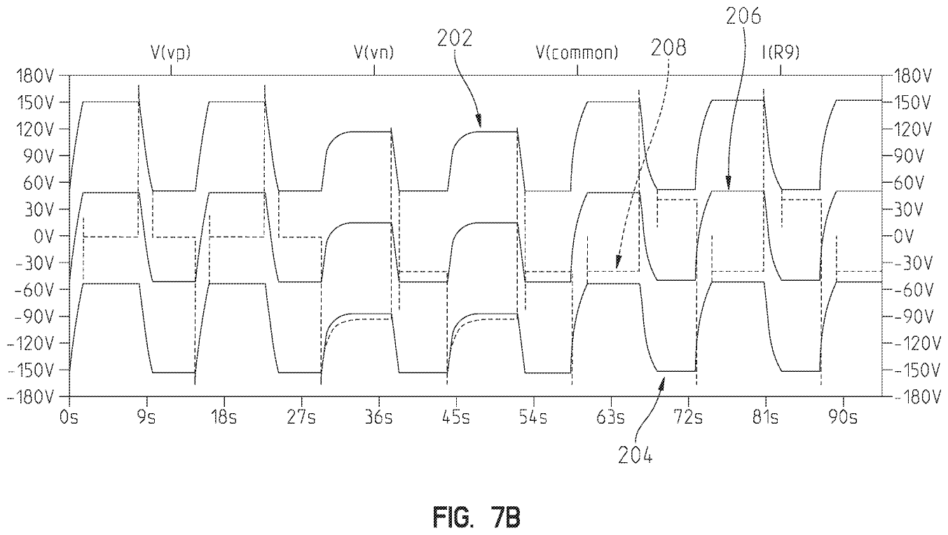

In an IMD in accordance with the present disclosure (e.g., a forced symmetry IMD 154), current is injected as a feedback to a measured common mode offset, and the common mode voltage is controlled to follow a specific signal, as shown in the chart shown in FIG. 7A. As shown here, for a no-fault condition, an asymmetrical fault condition, and a symmetrical fault condition, a positive bus bar voltage trace 202, and a negative bus bar voltage 204 have a stepped shape by remaining equally spaced apart, regardless of the type of fault, such that a common voltage 206 does not change because of the balancing function of the forced symmetry IMD 154. The current required to maintain the balance, as denoted by line 208, which may be measurements taken at an IMD node (e.g., R9 shown on FIG. 6), can be seen to change depending on whether the fault is not present (left third of the graph), whether there is an asymmetric fault (middle portion of the graph), or whether there is a symmetric fault condition (right third of the graph). The voltages from DC+/−bus bars to the person never exceed 675V, but the current from the balancing/injection 208 can be used to measure the resistance/capacitance of the leakage current/power. In some instances, a controller may be used to inject current into the system 150 based on whether a fault is present (e.g., no fault, asymmetric fault, or symmetric fault) and/or such that the Vcommon follows the Vreference. For instance, the controller may be used to change the current of the forced symmetry IMD 154 as denoted by line 208 in response to one or more faults (e.g., symmetric and/or asymmetric faults).

In reference to FIG. 7B, at low voltage (200V), the compensation cannot achieve the full amplitude, and the wave form shows an RC-curve instead of a square wave with the sloped transitions. As shown in FIG. 7C, at no voltage (0.1V) there is no measurement possible because the voltage between DC+/−across the DC bus bars is used for the injection.

A first embodiment for an exemplary circuit 300 that includes an example of a forced symmetry IMD in accordance with the disclosure is shown in FIG. 6, which operates according to the trends shown in FIG. 7A-7C. In particular, the forced symmetry IMD 302 of FIG. 6 may be an example of the forced symmetry IMD 154 of FIG. 5. In the circuit 300, a voltage source 1026 is connected across the DC Bus bars 104 and 106. An exemplary IMD 302 is generally shown between two nodes connected at the bus bars, and includes a power source 1036 providing a voltage/current and connected between ground and a resistor 1010, for example, a 10K Ohm resistor. The resistor is connected between two diodes 1046 and 1048 across two series resistors 1012 and 1014. A voltage node (e.g., an offset voltage) between the two resistors 1014 and 1012 is connected to a common detector (e.g., a first detector 1020) that includes an internal impedance or resistor 1004. Two transistors 1056 and 1058 are connected between the node and the bus bars via gap resistors 1000 and 1002.

As can be seen in FIG. 6, the metal oxide semiconductor field-effect transistor (MOSFET) transistors 1056 and 1058 have their respective drains connected to the respective DC bus bar, their sources connected to the voltage node, and their gates connected across the series resistors 1014 and 1012, which are also in parallel circuit connection with the diodes 1046 and 1048 and also the voltage source 1036. In this arrangement, control of the transistors 1056 and 1058 in their linear range, not in an on/off condition, can accomplish a tracking or floating of the voltage detected by the first detector 1020 to match the common voltage Vcommon, which can be found on the gap node between gap resistors 1006 and 1008 (e.g., detected by the second detector 1022). The gap resistors 10006 and 1008 may be 1 mega ohm resistors. In some instances, one or more components of the forced symmetry IMD 302 may be in electrical communication with a controller. For instance, the controller may use measurements of the detectors (e.g., the first detector 1020 at resistor 1004 and the second detector Vcommon 1022) to accomplish a tracking or floating of the common voltage Vcommon to follow a reference voltage. For instance, based on the offset voltage (e.g., the voltage at 1004 that is measured by the first detector 1020) and/or the Vcommon (e.g., the voltage measured by the second detector 1022 between 1006 and 1008), the controller may control the current and/or voltage of the power source 1036. For example, the controller may use a feedback loop to increase, decrease, and/or otherwise alter (e.g., changing from sinusoidal to square wave and so on) the voltage/current provided by the power source 1036 such that the Vcommon follows the Vreference. For instance, if the detected Vcommon is below Vreference by a certain amount, then the controller may change the voltage/current provided by the power source 1036 in order to increase Vcommon so that it matches Vreference. Vreference is a predefined voltage signal (e.g., a square wave, sinusoidal wave, or other type of signal) for the forced symmetry IMD 154. The Vreference may be based on components of the system 150 and/or the forced symmetry IMD 154. A controller may determine the Vreference as a voltage signal such that the controller is capable of measuring the capacitance and/or the resistance to ground for the forced symmetry IMD 154.

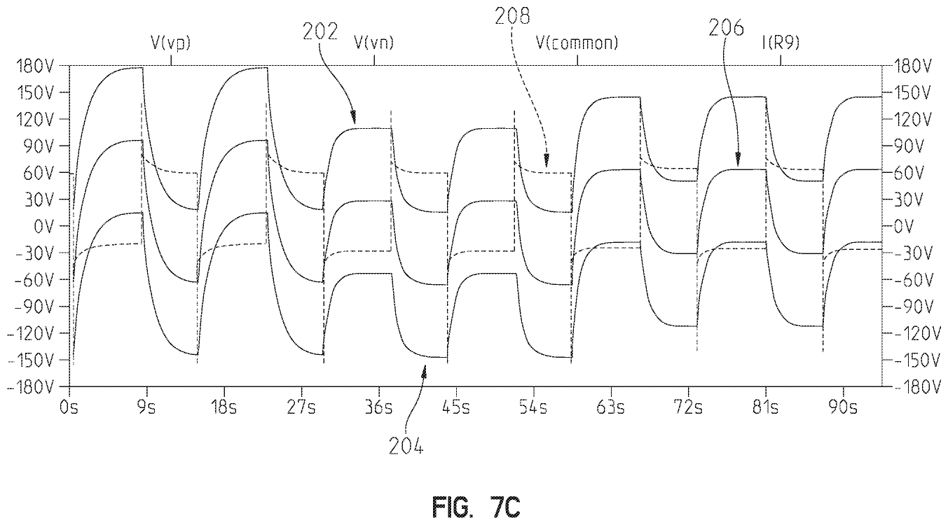

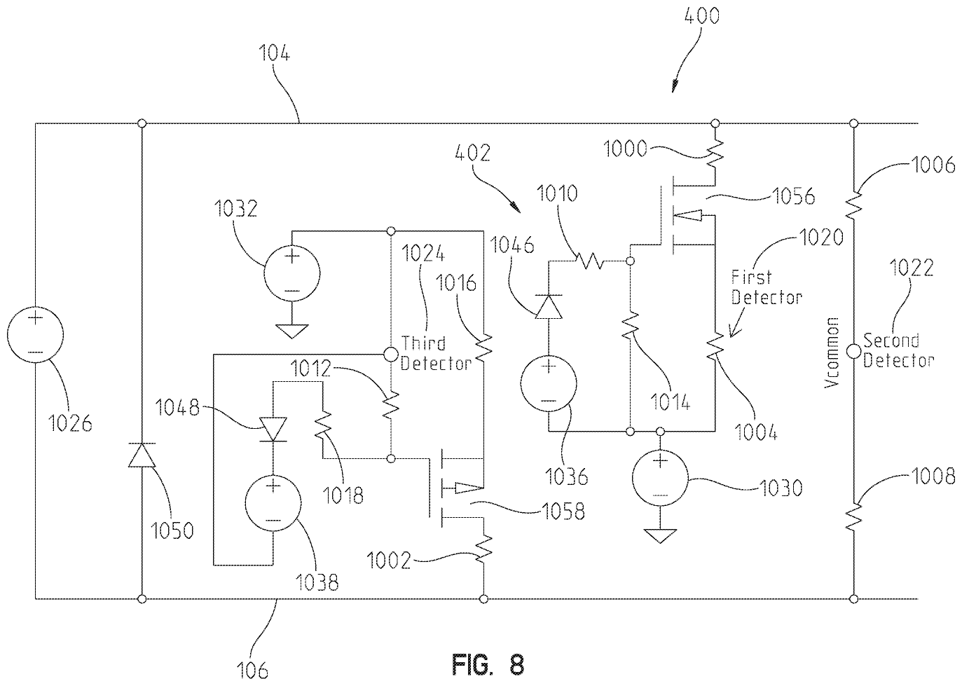

A second embodiment of a circuit 400 that includes an example of a forced symmetry IMD in accordance with the disclosure is shown in FIG. 8. In particular, the forced symmetry IMD 402 of FIG. 8 may be an example of the forced symmetry IMD 154 of FIG. 5. In the circuit 400, a voltage source 1026 is connected across the DC Bus bars 104 and 106 along with a diode 1050. Further, in this embodiment, a separate portion of the IMD 402 is operating relative to each of the two bus bars 104 and 106. For each bar, the common voltage Vcommon is the same and present between two gap resistors 1006 and 1008. For the positive bar 104, a measurement resistor 1000 is connected to the drain of a transistor 1056. A gate is connected between two resistors 1010 and 1014. The resistor 1010 may be a 10 k ohm resistor and the resistor 1014 may be a 10 megaohm resistor. Resistor 1010 is connected to the positive pole of a voltage supply 1036 via a diode 1046, and resistor 1014 is connected to the negative pole of 1036 such that a current and voltage are available to flow regardless of whether the DC bus is active. The voltage is measured by a measurement device (e.g., by the first or third detectors 1020/1024 at 1004 and/or 1016), and a positive voltage source 1030 is connected to the source of the transistor via a resistor 1004 and also to the negative pole of the supply 1036. The same arrangement is present on the negative bus bar 106 but with a negative voltage source 1032.

During operation of the second embodiment for the IMD 402, the circuit that pulls the DC− up is connected to the positive voltage source 1030 (e.g., 50V) and the circuit that pulls the DC+ down is connected to a negative voltage source 1032 (e.g., −50V). The reverse diodes (1046 and 1048) are added, one each, to prevent negative bias for an unloaded circuit. In some instances, one or more components of the forced symmetry IMD 402 may be in electrical communication with a controller. In some variations, a first detector 1020 may be used to determine a first node voltage (e.g., offset voltage) at the resistor 1004, a second detector 1022 may be used to determine the Vcommon (common voltage) between resistors 1006 and 1008, and a third detector 1024 may be used to determine a second node voltage at 1016. The controller may use the first node voltage, the second node voltage, and/or the Vcommon to control the power source 1036 and/or 1038. For example, the controller may use a feedback loop to increase, decrease, and/or otherwise alter (e.g., changing from sinusoidal to square wave and so on) the voltage/current provided by the power source 1036 and/or 1038 such that the Vcommon follows the Vreference.

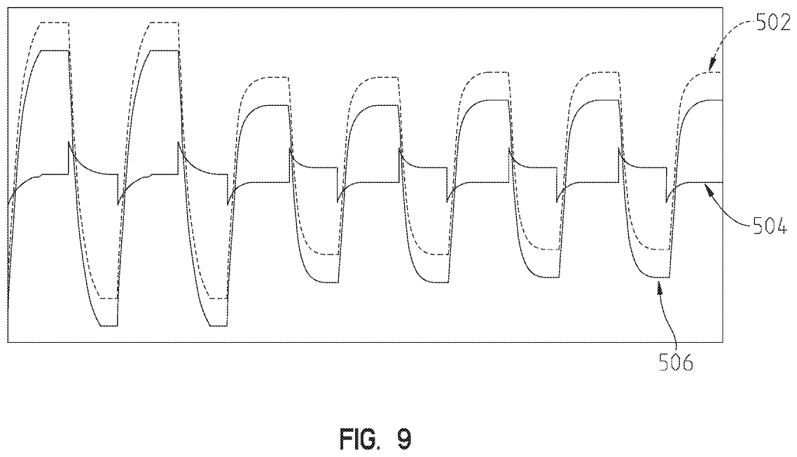

In this embodiment, the IMD can advantageously measure impedance to ground, because there is current still flowing from the voltage sources, for instance at 10V between DC+ and DC−, even if the bus is not active, as shown in FIG. 9, in which the voltage of the positive bus is shown as 502, the voltage at the negative bus is shown as 504, and the current through a respective one or the two IMD portions is shown as 506.

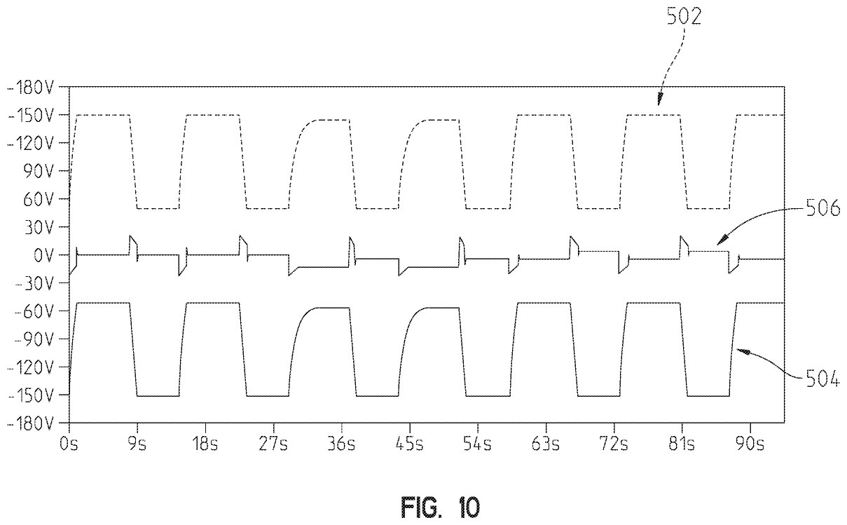

It is noted that the amplitude of the voltage is lower, because the resistances in the injection circuit are limiting the signal. To determine the resistance and capacitance to ground, a square wave with a specific slope can be used, as shown in FIG. 10. On the slopes, the current drawn by the circuit is showing an offset due to dV/dt and the Y-capacitance, and a slope due to the resistance to ground. After the voltages have stabilized, the leakage current can be used to measure only the resistance.

If the injection circuit ‘saturates’, i.e., the transistors, switches or other components used in their place are completely closed instead of in an analog range, an RC-charge/discharge slope can be seen. Matching this (e.g., controlling the power sources by the controller to match the Vcommon to the Vreference) can be used to determine the capacitance, and when the voltage stabilizes the current can be used to determine the resistance.

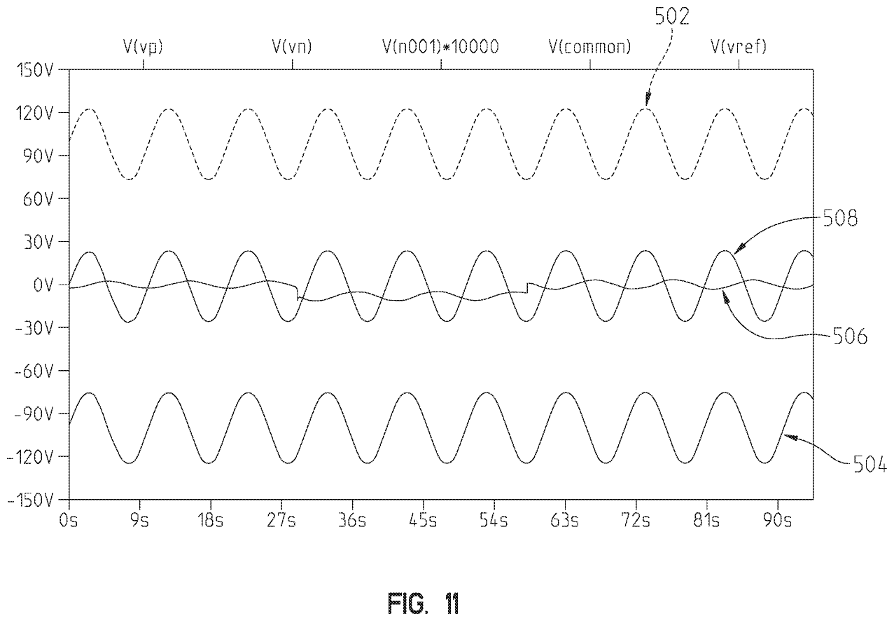

Alternatively, a sinusoidal signal can be used (e.g., the controller controlling the power sources to provide a sinusoidal signal), as shown in FIG. 11, which also shows the common voltage 508 (voltage between the two gap resistors R12 and R13 to which the forced symmetry IMD balances to. The amplitude, phase shift and optionally offset of the current can be used to derive the resistance and capacitance to ground.

Combinations of wave forms can be used, for instance sine waves with multiple frequencies, or a square wave plus a sine wave superimposed, amplitudes can vary, and the like.

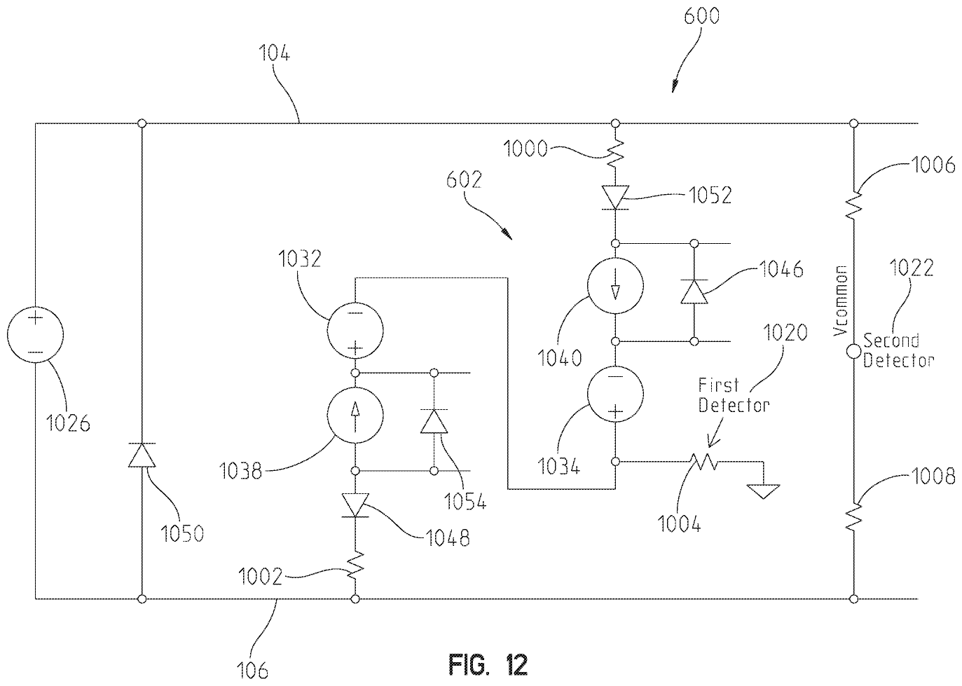

A third embodiment for a circuit 600 that includes an example of a forced symmetry IMD in accordance with the disclosure is shown in FIG. 12. In particular, the forced symmetry IMD 602 may be an example of the forced symmetry IMD 154 of FIG. 5. In the circuit 600, a voltage source 1026 is connected across the DC Bus bars 104 and 106 along with a diode 1050. Further in this embodiment, a current source is used to help balance the voltage detected on the IMD 602 node. More specifically, two voltage sources 1032 and 1034 are connected in series along the IMD 602 node, with the detector 1020 having internal resistance 1004 disposed between the two sources 1032 and 1034. Each source is connected to a current source 1040 or 1038 that provides current towards each respective voltage source. Diodes 1048 and 1052 can optionally be used, along with gap resistors 1000 and 1002, to complete the node. Additionally, and/or alternatively, diodes 1054 and 1046 can also be used. During operation, the current sources 1038 and 1040 and voltage sources 1032 and 1034 are used to actively balance the IMD 602 and track the voltage Vcommon of the gap node based on the voltage sensed by the detector. In this way, the current passing through the IMD node 602, in any direction and rate of change, permits the calculation of the leakage resistance and capacitance. In a variation of the system 600, the voltage sources 1032 and 1034 can also be omitted, in which case there might not be an ability to measure leakage resistance and capacitance when there is no power on the DC Bus bar. In some instances, one or more components of the forced symmetry IMD 602 may be in electrical communication with a controller. In some variations, a first detector 1020 (coupled to resistor 1004) may be used to determine the IMD node voltage and a second detector 1022 may be used to determine the Vcommon voltage. For instance, the controller may use the node voltage and/or the Vcommon to control the power source 1038 and/or 1040. For example, the controller may use a feedback loop to increase, decrease, and/or otherwise alter (e.g., changing from sinusoidal to square wave and so on) the voltage/current provided by the power source 1038 and/or 1040 such that the Vcommon follows the Vreference.

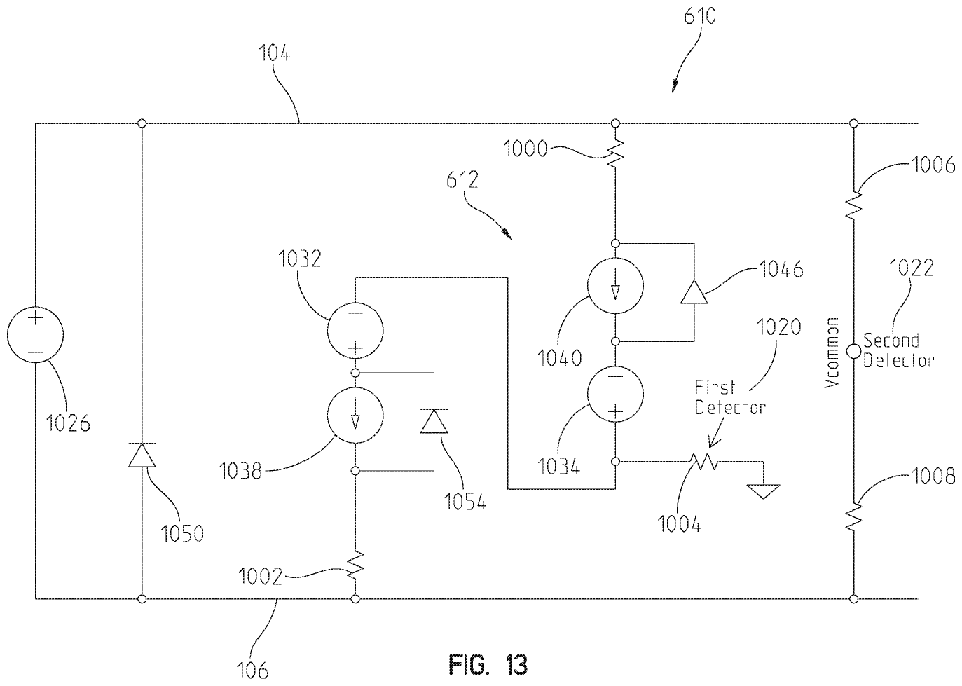

A fourth embodiment for a circuit 610 that includes an example of a forced symmetry IMD in accordance with the disclosure is shown in FIG. 13. In particular, the forced symmetry IMD 612 may be an example of the forced symmetry IMD 154 of FIG. 5. In the circuit 610, a voltage source 1026 is connected across the DC Bus bars 104 and 106 along with a diode 1050. Further, in this embodiment is similar to the third embodiment except the diodes 1048 and 1052 from FIG. 12 have been removed. More specifically, two voltage sources 1032 and 1034 are connected in series along the IMD 612 node, with the detector 1020 having internal resistance 1004 disposed between the two sources 1032 and 1034. Each source is connected to a current source 1040 or 1038 that provides current towards each respective voltage source. During operation, the current and voltage sources 1040, 1034, 1038, and 1032 are used to actively balance the IMD 612 and track the voltage Vcommon of the gap node based on the voltage sensed by the detector. In this way, the current passing through the IMD node 612, in any direction and rate of change, permits the calculation of the leakage resistance and capacitance. In some instances, one or more components of the forced symmetry IMD 612 may be in electrical communication with a controller. In some variations, a first detector 1020 at resistor 1004 may be used to determine the IMD node voltage and a second detector 1022 may be used to determine the Vcommon voltage. For instance, the controller may use the node voltage and/or the Vcommon to control the power source 1038 and/or 1040. For example, the controller may use a feedback loop to increase, decrease, and/or otherwise alter (e.g., changing from sinusoidal to square wave and so on) the voltage/current provided by the power source 1038 and/or 1040 such that the Vcommon follows the Vreference.

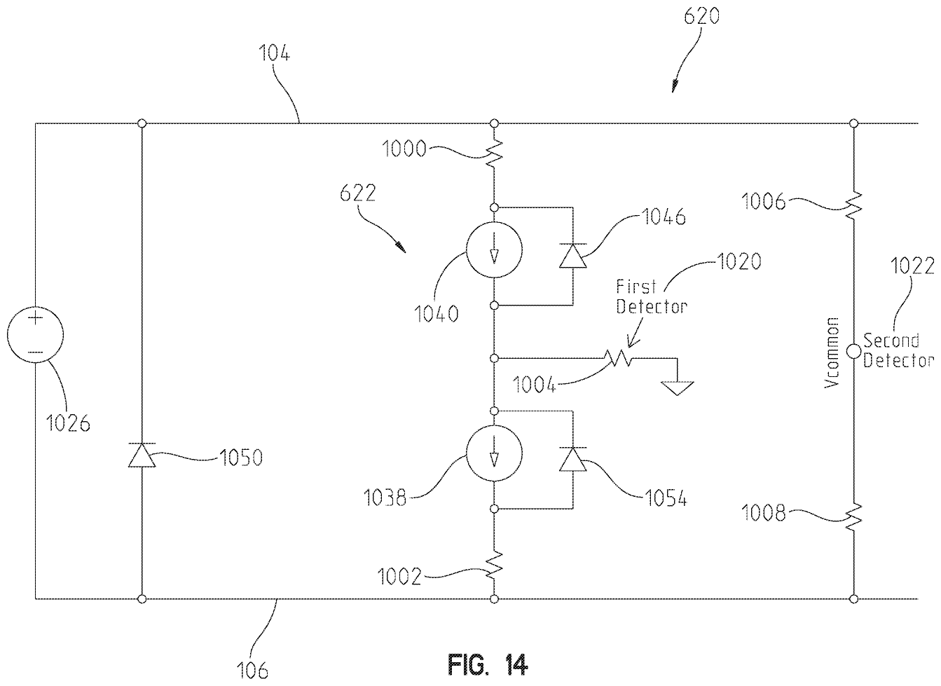

A fifth embodiment for a circuit 620 that includes an example of a forced symmetry IMD in accordance with the disclosure is shown in FIG. 14. In particular, the forced symmetry IMD 622 may be an example of the forced symmetry IMD 154 of FIG. 5. This embodiment may be similar to the fourth embodiment of FIG. 13 except it removes the two voltage sources 1032 and 1034 of FIG. 13. More specifically, two current sources 1040 and 1038 are connected in series along the IMD 622 node, with the detector 1020 having internal resistance 1004 disposed between the two sources 1040 and 1038. During operation, the current sources 1038 and 1040 are used to actively balance the IMD 622 and track the voltage Vcommon of the gap node based on the voltage sensed by the detector 1020. In this way, the current passing through the IMD node 622, in any direction and rate of change, permits the calculation of the leakage resistance and capacitance. In some instances, one or more components of the forced symmetry IMD 622 may be in electrical communication with a controller. In some variations, a first detector 1020 may be used to determine the IMD node voltage and a second detector may be used to determine the Vcommon voltage. For instance, the controller may use the node voltage and/or the Vcommon to control the power source 1040 and/or 1038. For example, the controller may use a feedback loop to increase, decrease, and/or otherwise alter (e.g., changing from sinusoidal to square wave and so on) the voltage/current provided by the power source 1040 and/or 1038 such that the Vcommon follows the Vreference.

In all embodiments for the forced symmetry IMD herein, all resistors should be understood to be any kind of device having an impedance, not just resistors. Moreover, the transistors described are intended to indicate electrical devices that control the flow of current there-through and thus any other appropriate device can also be used.

Overall, the mode of operation of the various embodiments of the forced symmetry IMDs described herein is similar in that the forced symmetry IMD node, whether connected across the bus bars or separately, can include a voltage/current source used to dynamically balance the voltage of the bars relative to one another, and also optionally create a current passing through the forced symmetry IMD node that can be used to determine the system's leakage resistance and capacitance, both when the system is operating normally and also when imbalanced leakage may exist on one node or another. In other words, the embodiments for the forced symmetry IMDs described herein operate to control voltage to ground for each bus bar separately, thus balancing the bus bar and also limiting the maximum pull that exists from each bus bar, to correspondingly control the maximum energy that can pass through a person for reasons of safety.

To put it another way, a controller may be used control the current within the forced symmetry IMD 154 such that voltage is being pulled from either the bus 104 or the bus 106 in order to control/limit the resistance, voltage, and/or capacitance to ground. For instance, based on the Vcommon and/or the currents flowing through resistors 1000 and 1002 (shown in FIGS. 6, 8, 12, 13, and 14), the capacitance and/or resistance to ground may be determined. This may be an added protection to the system 150 by limiting the resistance, capacitance, and/or voltage to ground as in the case of failure (e.g., the person 110 touching the bus 104 and/or 106), the current flowing through the person may be limited. Further, as described above, the system 150 may be at a higher voltage (e.g., 1250V) and/or current (e.g., 3000 A). By using the controller to control the current through the forced symmetry IMD 154 such that the Vcommon follows the Vreference, the forced symmetry IMD 154 is able to limit the resistance, capacitance, and/or voltage to ground to keep them at safer levels if a person comes into contact with the system 150 (e.g., the bus 104 and/or 106).

In the embodiments shown in FIGS. 6, 8, 12, 13, and 14, the resistors 1000 and 1002 within the forced symmetry IMD 154 are designed to limit the steady state leakage current in order to protect the person 110 to protect the rails and they also may function for the measurement for resistance and capacitance to ground in case the transistors or current sources saturate.

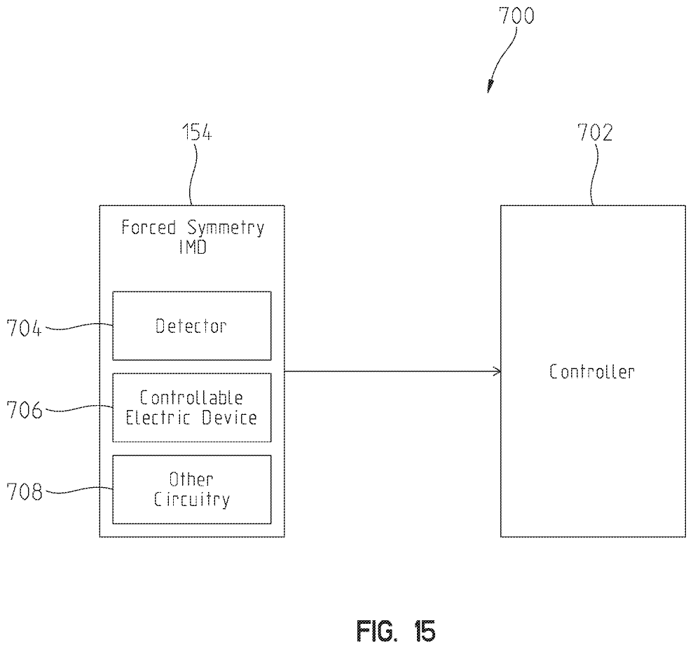

FIG. 15 is a schematic illustration of a block diagram depicting an exemplary control system for controlling the forced symmetry IMD in accordance with the disclosure. In particular, the control system 700 includes the forced symmetry IMD 154 and a controller 702. The forced symmetry IMD 154 includes a detector 704, a controllable electric device 706, and other circuitry 708. Examples of the forced symmetry IMD 154 and its components are described herein such as in FIGS. 6, 8, 12, 13, 14, 15, and 16.

The controller 702 is not constrained to any particular hardware, and the controller's configuration may be implemented by any kind of programming (e.g., embedded Linux) or hardware design—or a combination of both. For instance, the controller 702 may be formed by a single processor, such as general purpose processor with the corresponding software implementing the described control operations. On the other hand, the controller 702 may be implemented by a specialized hardware, such as an ASIC (Application-Specific Integrated Circuit), an FPGA (Field-Programmable Gate Array), a DSP (Digital Signal Processor), or the like. As described above, the controller 702 may provide information (e.g., instructions and/or commands) to control the current (e.g., the injected current) of the forced symmetry IMD 154 and/or perform other functionalities.

In some instances, the controller 702 may be a dedicated controller or processor for controlling the forced symmetry IMD 154. In other instances, the controller 702 may be part of the EVSE and may perform additional functionalities for the EVSE.

In some examples, the controller 702 is in electrical communication with memory. The memory may be and/or include a computer-usable or computer-readable medium such as, but not limited to, an electronic, magnetic, optical, electromagnetic, infrared, or semiconductor computer-readable medium. More specific examples (e.g., a non-exhaustive list) of the computer-readable medium may include the following: an electrical connection having one or more wires; a tangible medium such as a portable computer diskette, a hard disk, a time-dependent access memory (RAM), a ROM, an erasable programmable read-only memory (EPROM or Flash memory), a compact disc read-only memory (CD_ROM), or other tangible optical or magnetic storage device. The memory may store corresponding software such as computer-readable instructions (code, script, etc.). The computer instructions being such that, when executed by the controller 702, cause the controller 702 to control the forced symmetry IMD 154 as described herein.

The controller 702 may be configured to control the current (e.g., the injected current) of the forced symmetry IMD 154 and/or determine the capacitance, resistance, impedance, and/or voltage to ground. For instance, the controller 702 may be used such that the measured common mode voltage may be controlled to follow the reference signal (e.g., the reference voltage). For instance, the measured common mode voltage and/or the node voltages may provide the information to derive the impedance (e.g., resistance, voltage, and capacitance) of the system to ground. In other words, referring to FIG. 6, the controller 702 may receive voltage measurements such as the Vcommon from the second detector 1022 and/or a node voltage (e.g., an IMD node voltage) from resistor 1004/the first detector 1020. Based on the Vcommon and/or the node voltage, the controller 702 may control the current/voltage of the power source 1036 such that the Vcommon may match and/or follow a reference voltage (Vreference). For instance, the forced symmetry IMD 154 may be a feedback loop that is controlled by the controller. The controller 702 regulates the feedback loop such that the forced symmetry IMD 154 either pulls current up or down from the bus 104 and/or 106. As such, the control loop controls the current going through 1000 or 1002. Additionally, and/or alternatively, the controller 702 may determine the capacitance to ground as well based on the dynamic signal and/or resistance capacitance (RC) curve.

In some instances, the controller 702 may control the power source 1036 to inject a sinusoidal, square wave, a mixture of both, and/or other types of voltage and/or current signals to the forced symmetry IMD 154. Additionally, and/or alternatively, the controller 702 may determine the mode of the transistor (e.g., whether the transistors 1056 and/or 1058) are in a linear mode and/or saturated mode. Based on the mode of the transistor, the controller 702 may control the voltage/current of the forced symmetry IMD 154. For instance, based on the transistor being linear, the controller 702 may control the Vcommon to follow the Vreference. Based on the transistor being saturated, the controller 702 may reduce the amplitude of the Vreference so as to direct the transistors to becoming linear and/or may accept that the transistors are saturated and direct the Vcommon to follow an RC curve.

Referring to FIG. 8 and similar to FIG. 6, the controller 702 may receive voltage measurements such as the Vcommon from the second detector 1022 and/or the node voltages from the first and third detectors 1020 and 1024 at the resistors 1004 and 1016. Based on the Vcommon and/or the node voltages, the controller 702 may control the current/voltage of the power sources 1038 and/or 1036 such that the Vcommon may match and/or follow Vreference. Referring to FIGS. 12-14 and similar to FIGS. 6 and 8, the controller 702 may receive voltage measurements such as the Vcommon from the second detector 1022 and/or the node voltage from the first detector 1020 at the resistor 1004. Based on the Vcommon and/or the node voltage, the controller 702 may control the current/voltage of the power sources 1038 and/or 1040 such that the Vcommon may match and/or follow Vreference.

In some instances, the controller 702 is set to control the Vcommon to follow the Vreference. The Vreference may be determined by the controller 702 and/or based on determining and/or limiting the impedance (e.g., voltage, resistance, and/or capacitance) to ground so as to prevent injury to the person 110 and/or an animal (e.g., based on a determination that Vcommon is unable to follow Vreference due to a fault).

In some variations, the controller 702 is configured to determine a reference voltage signal for the forced symmetry IMD. As mentioned previously, the common voltage may follow the reference voltage signal. Additionally, and/or alternatively, the controller 702 is configured to change a characteristic of the reference voltage signal. For instance, the characteristic of the reference voltage signal may include, but is not limited to, a type of wave, a frequency of the reference voltage signal, an amplitude of the reference voltage signal, and/or slope of edges of the reference voltage signal.

In other words, the controller 702 may be configured to change a type of wave such as from one or more square waves to one or more sinusoidal waves or so on. For instance, initially, the reference voltage signal may be a square wave and the controller 702 may change the signal to a sinusoidal wave. Additionally, and/or alternatively, the controller 702 may change the reference voltage signal to one or more square waves and one or more sinusoidal waves (e.g., the first few waves in the signal may be square waves and the next few waves may be sinusoidal waves).

The controller 702 may be configured to determine the reference voltage signal and/or change the characteristic of the reference voltage signal based on an operational status of the bus (e.g., bus bars 104 and 106). The operational status of the bus may include, but is not limited to balanced resistance to ground, unbalanced resistance to ground, capacitance to ground, voltage between the first bus bar and the second bus bar, or noise within the system.

The controller 702 may determine the resistance to ground based on the common voltage at the common node (e.g., using the second detector) and/or a current at the IMD node (e.g., using the first detector associated with 1004 in FIGS. 6, 8, and 12-14). For instance, for a square wave, when the common voltage settles (e.g., does not vary too much from a value), the controller 702 may determine a first common node voltage at that time and a first current at the IMD node. Then, when the square wave settles to the other value (e.g., goes to the negative value from the positive value), the controller 702 may determine a second common node voltage and a second current at the IMD node. For balanced resistance to ground, the controller 702 may determine the difference in the first and second voltages and difference in the first and second currents, and uses the differences to determine the resistance to ground value.

In some instances, for unbalanced resistance to ground (asymmetrical), the controller 702 may use the voltage between the first bus bar 104 and second bus bar 106 combined with common voltage and divided by the measured current at the IMD node.

The controller 702 may determine the capacitance to ground based on the slope of the reference voltage signal. For instance, the reference voltage signal, as described above, may include a plurality of steady state values that change between positive values and negative values. The transitions between the positive values and negative values may include slopes (e.g., they might not go straight down, but are sloped transitions from positive to negative and negative to positive). The controller 702 may determine the capacitance to ground based on these sloped transitions.

Based on the resistance to ground value, the controller 702 may compare the resistance to ground value with one or more thresholds. If the resistance to ground value is below a certain threshold, the controller 702 may determine the common voltage is unable to follow the reference voltage signal, and the controller 702 may reduce the amplitude of the reference voltage signal. Based on the capacitance to ground value as well as the resistance to ground value, the controller 702 may change a frequency of the reference voltage signal. For instance, based on the capacitance to ground value being above a threshold, the controller 702 may decrease the frequency.

For a sinusoidal wave, the controller 702 may measure a phase shift and/or amplitude of the measured current at the IMD node. Then, the controller 702 may determine the resistance to ground and capacitance to ground based on the phase shift and/or the amplitude of the measured current at the IMD node.

For the sinusoidal wave, based on the resistance to ground and capacitance to ground, the controller 702 may determine/change the reference voltage signal. For instance, the controller 702 may compare the resistance to ground and/or the capacitance to ground with one or more thresholds. Based on the capacitance to ground being above a threshold, the controller 702 may adjust the reference voltage signal to decrease the frequency of the reference voltage signal and/or to attenuate and/or add an offset to the reference voltage signal. Based on the resistance to ground being above a threshold, the controller 702 may adjust the reference voltage signal to decrease the frequency of the reference voltage signal and/or to attenuate and/or add an offset to the reference voltage signal.

In some examples, the controller 702 may change the reference voltage signal based on the noise within the system. In some instances, the controller 702 may change the reference voltage signal based on the voltage of the first and second bus bar. For instance, if the voltage of the first and/or second bus bar are below a threshold, the controller 702 may change the amplitude (e.g., increase the amplitude) of the reference voltage signal.

In some variations, the controller 702 may determine the resistance to ground value as described above. Based on the resistance to ground value being below a threshold, the controller 702 may control the electric power source. For instance, the controller 702 may provide a notification to a separate device indicating a warning (e.g., a low resistance to ground value for the forced symmetry IMD 154) and/or a service request to service the system 150. Additionally, and/or alternatively, the controller 702 may de-energize the system power source (e.g., V1 on FIG. 6).

Additionally, and/or alternatively, the controller 702 may determine the capacitance to ground value as described above. Then, based on the capacitance to ground value, the controller 702 may control the electric power source. For example, the controller 702 may compare the capacitance to ground value with a threshold. Based on the capacitance to ground value being above the threshold, the controller 702 may provide a notification to a separate device indicating a warning (e.g., a high capacitance to ground value for the forced symmetry IMD 154) and/or a service request to service the system 150. Additionally, and/or alternatively, the controller 702 may de-energize the system power source (e.g., voltage source 1026 on FIG. 6).

In some instances, the controller 702 may control the electric power source based on one or more voltages associated with the first and second bus bar (e.g., a first voltage of the first bus bar to ground value, second voltage of the second bus bar to ground value, and/or third voltage between first bus bar and second bus bar value). For instance, based on the voltages exceeding one or more thresholds, the controller 702 may provide a notification to a separate device indicating a warning (e.g., a voltage value for the forced symmetry IMD 154) and/or a service request to service the system 150. Additionally, and/or alternatively, the controller 702 may de-energize the system power source (e.g., voltage source 1026 on FIG. 6).

In some instances, the controller 702 may control the electric power source based on a predetermined human body resistance value as indicated by IEC 60479 and/or IEC 61851.

In some examples, the controller 702 may control the current/voltage power source (e.g., voltage sources 1036, 1038, 1040 in FIGS. 6, 8, and/or 12-14) as needed. For instance, the controller 702 may set the current for the current/voltage power sources of the forced symmetry IMD 154 to OA in order not to load the bus with any resistance to ground. In other examples, the controller 702 may set the current for the current/voltage power sources of the forced symmetry IMD 154 to maximum to discharge the X and Y capacitors on the bus (e.g., the DC bus). In yet other examples, the controller 702 may set the current for the current/voltage power sources of the forced symmetry IMD 154 to somewhere in-between OA and maximum, (e.g., between in the linear region) to provide a discharge path and still maintain functionality of the forced symmetry IMD 154 with a faster reaction time and/or higher noise immunity.

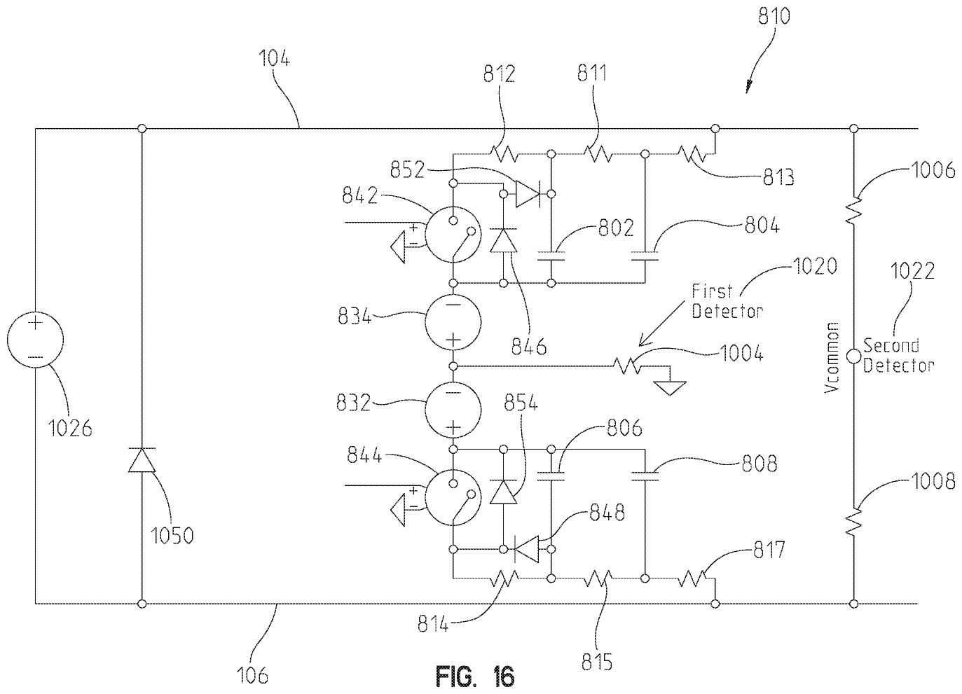

A sixth embodiment for a circuit 810 that includes an example of a forced symmetry IMD in accordance with the disclosure is shown in FIG. 16. In particular, the forced symmetry IMD shown in circuit 810 may be an example of the forced symmetry IMD 154 of FIG. 5. In circuit 810, a voltage source 1026 is connected across the DC Bus bars 104 and 106 along with a diode 1050. Further to prevent a thermal runaway type of effect when using MOSFETs in a linear mode, which may be similar to secondary breakdown in bipolar transistors, circuit 810 uses pulse width modulation (PWM) for the MOSFET with an impedance and filter. In particular, the circuit 810 includes impedances 812 and 814 in series with the MOSFETs (e.g., the switches 842 and 844) and filtered by capacitors 802 and 806. Additionally, and/or alternatively, the circuit 810 may further include one or more additional filters (e.g., RC filters). As shown, a first T-filter (shown by resistors 811 and 813 as well as capacitor 804) and a second T-filter (resistors 815 and 817 as well as capacitor 808) are used. Diodes 846 and 854 may be part of the switches 842 and 844. Diodes 848 and 852 are optional freewheeling diodes for the energy stored in the impedance devices 812 and 814. Voltage sources 832 and 834 optionally may be used to measure if voltage source 1026 is close to 0 Volts.

In some instances, one or more components of the forced symmetry IMD of FIG. 8 may be in electrical communication with a controller such as the controller 702. The controller 702 may control the components of the forced symmetry IMD as described above. In some variations, a first detector 1020 at resistor 1004 may be used to determine the IMD node voltage and a second detector 1022 may be used to determine the Vcommon voltage between resistors 1006 and 1008. For instance, the controller 702 may use the node voltage and/or the Vcommon to control the power source 832 and 834 and/or switches 842 and 844. For example, the controller may use a feedback loop to increase, decrease, and/or otherwise alter (e.g., changing from sinusoidal to square wave and so on) the voltage/current provided by the power source 1032 and/or 1034 such that the Vcommon follows the Vreference.

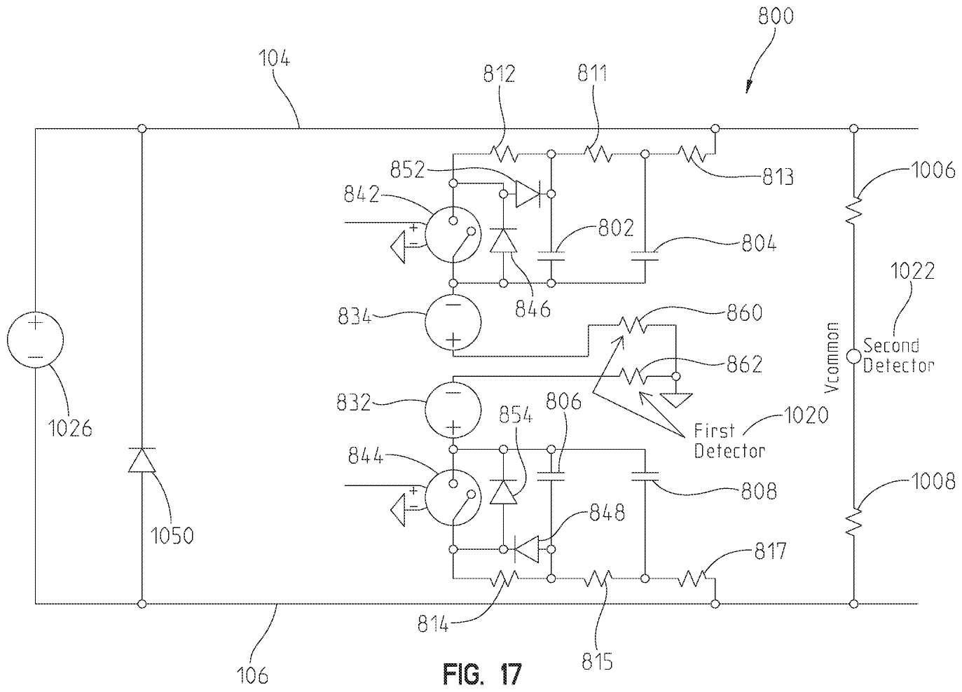

A seventh embodiment for a circuit 800 that includes an example of a forced symmetry IMD in accordance with the disclosure is shown in FIG. 17. In particular, the forced symmetry IMD of circuit 800 may be an example of the forced symmetry IMD 154 of FIG. 5. In the circuit 800, a voltage source 1026 is connected across the DC Bus bars 104 and 106 along with a diode 1050. Further, the circuit 800 is similar to circuit 810 except the first detector 1020 from FIG. 16 that is at resistor 1004 is split by two resistors 860 and 862, which allows for more precise measurement and control of the impedance of the IMD to earth (ground) for each leg. Combined with accurate voltage measurements of each rail to round, the impedances for 814, 815 and 817, or 811, 812, and 813 may be determined on the fly.

In some instances, one or more components of the forced symmetry IMD may be in electrical communication with a controller such as the controller 702. The controller 702 may control the components of the forced symmetry IMD as described above.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A system, comprising:
an electric system power source configured to deliver electrical power to a bus, the bus including a first bus bar and a second bus bar;
a common node connected across the first bus bar and the second bus bar, the common node having a common voltage when electric power is delivered to the bus; and
a forced symmetry insulation monitoring device (IMD) disposed along an IMD node connected to at least one of the first bus bar and the second bus bar, the forced symmetry IMD comprising a connection to ground and one or more IMD power sources,
wherein the one or more IMD power sources of the forced symmetry IMD is configured to control the common voltage on the common node based on a currently detected common voltage and a reference voltage signal.

2. The system of claim 1, further comprising:
a first detector configured to detect the currently detected common voltage at the common node and provide the currently detected common voltage to a controller; and
the controller configured to:
receive the currently detected common voltage; and
direct the one or more IMD power sources to provide current to the forced symmetry IMD to match the reference voltage signal using a feedback loop and the currently detected common voltage.

3. The system of claim 2, further comprising:
a second detector configured to detect a node voltage at the IMD node and provide the node voltage to the controller, and
wherein the controller is configured to direct the one or more IMD power sources to provide current to the forced symmetry IMD to match the reference voltage signal using the feedback loop, the currently detected common voltage, and the node voltage.

4. The system of claim 2, wherein the controller is configured to:
determine a reference voltage signal for the forced symmetry IMD; and
change a characteristic of the reference voltage signal, wherein the characteristic of the reference voltage signal is a type of wave, a frequency of the reference voltage signal, an amplitude of the reference voltage signal, or slope of edges of the reference voltage signal.

5. The system of claim 4, wherein the type of wave is one or more square waves, one or more sinusoidal waves, or a mixture of both the one or more square waves and the one or more sinusoidal waves.

6. The system of claim 4, wherein the controller configured to change the characteristic of the reference voltage signal based on operational status of the bus, wherein the operational status of the bus comprises balanced resistance to ground, unbalanced resistance to ground, capacitance to ground, voltage between the first bus bar and the second bus bar, or noise within the system.

7. The system of claim 2, wherein the controller is configured to:
determine a resistance to ground value based on the common voltage at the common node and a current at the IMD node;
control the electric power source based on the resistance to ground value.

8. The system of claim 7, wherein the controller is configured to:
determine a capacitance to ground value based on the common voltage at the common node and a current at the IMD node, and
wherein controlling the electric system power source is further based on the capacitance to ground value, first voltage of the first bus bar to ground value, second voltage of the second bus bar to ground value, third voltage between first bus bar and second bus bar value, and a predetermined human body resistance value.

9. The system of claim 7, wherein the controller is configured to control the electric power source by providing a notification to a separate device indicating a warning or to service the system, or de-energize the electric system power source.

10. The system of claim 1, wherein the forced symmetry IMD further comprises a first voltage source and a second voltage source, wherein the first voltage source is located between a first IMD power source, of the one or more IMD power sources, and the IMD node, and wherein the second voltage source is located between a second IMD power source, of the one or more IMD power sources, and the IMD node.

11. The system of claim 10, wherein the forced symmetry IMD further comprises a first diode and a second diode, wherein the first diode is located between the first IMD power source and the first bus bar, and wherein the second diode is located between the second IMD power source and the second bus bar.

12. The system of claim 1, wherein the forced symmetry IMD further comprises a first transistor and a second transistor, wherein a drain of the first transistor is connected to a first bus bar, a source of the first transistor is connected to the IMD node, and a gate of the first transistor is connected to the one or more IMD power sources, and wherein a drain of the second transistor is connected to a second bus bar, a source of the second transistor is connected to the IMD node, and a gate of the second transistor is connected to the one or more IMD power sources.

13. The system of claim 1, wherein the forced symmetry IMD further comprises a first transistor, wherein a drain of the first transistor is connected to the first bus bar, a gate of the first transistor is connected to a first resistor and a second resistor, and a source of the first transistor is connected to a positive voltage source, and wherein the first resistor is connected to a first IMD power source of the one or more IMD power sources.

14. The system of claim 1, wherein the electric system power source is configured to deliver electrical power to the bus to charge or discharge a storage device.

15. The system of claim 14, wherein the storage device is a battery of an electric vehicle.

16. A forced symmetry insulation monitoring device (IMD), comprising:
a connection to ground; and
one or more IMD power sources, wherein the forced symmetry IMD is disposed along an IMD node connected to at least one of a first bus bar and a second bus bar of a bus, wherein the one or more IMD power sources of the forced symmetry IMD is configured to control the common voltage on the common node based on a currently detected common voltage and a reference voltage signal.

17. The forced symmetry IMD of claim 16, further comprising a first voltage source and a second voltage source, wherein the first voltage source is located between a first IMD power source, of the one or more IMD power sources, and the IMD node, and wherein the second voltage source is located between a second IMD power source, of the one or more IMD power sources, and the IMD node.

18. The forced symmetry IMD of claim 17, further comprising a first diode and a second diode, wherein the first diode is located between the first IMD power source and the first bus bar, and wherein the second diode is located between the second IMD power source and the second bus bar.

19. The forced symmetry IMD of claim 16, further comprising a first transistor and a second transistor, wherein a drain of the first transistor is connected to a first bus bar, a source of the first transistor is connected to the IMD node, and a gate of the first transistor is connected to the one or more IMD power sources, and wherein a drain of the second transistor is connected to a second bus bar, a source of the second transistor is connected to the IMD node, and a gate of the second transistor is connected to the one or more IMD power sources.

20. The forced symmetry IMD of claim 16, further comprising a first transistor, wherein a drain of the first transistor is connected to the first bus bar, a gate of the first transistor is connected to a first resistor and a second resistor, and a source of the first transistor is connected to a positive voltage source, and wherein the first resistor is connected to a first IMD power source of the one or more IMD power sources.
